(19) United States
(12) Patent Application Publication
(10) Pub. No.: US 2021/0348851 A1
(43) Pub. Date: Nov. 11, 2021

(54) HEAT DISSIPATION STRUCTURE OF HANDHELD DEVICE

(71) Applicant: ASIA VITAL COMPONENTS CO., LTD., New Taipei City (TW)

(72) Inventor: Ching-Hang Shen, New Taipei City (TW)

(21) Appl. No.: 16/867,568

(22) Filed: May 6, 2020

(51) Int. Cl. F28D 15/04; H05K 7/20

(52) U.S. Cl. CPC F28D 15/043; H05K 7/20336

(57) ABSTRACT

A heat dissipation structure of handheld device includes a hollow frame body and a two-phase flow heat exchange unit. The hollow frame body has a hollow receiving space at the center. The two-phase flow heat exchange unit has at least one two-phase flow conduction section. The two-phase flow heat exchange unit is disposed in the hollow receiving space and securely connected with the hollow frame body. The heat dissipation structure of handheld device can enhance the heat dissipation performance and the support structural strength of the handheld device.

### BACKGROUND OF THE INVENTION

### 1. Field of the Invention

The present invention relates generally to a heat dissipation structure of handheld device, and more particularly to a heat dissipation structure of handheld device, which can enhance the heat dissipation performance and the structural strength of the handheld device.

### 2. Description of the Related Art

Along with the multiplication of the performance and processing speed of the handheld mobile device, the internal electronic components of the handheld mobile device generate higher heat, which is conducted to the entire body of the handheld mobile device. As a result, a user's hand will feel hot and the electronic components may be overheated to burn down. Therefore, it is necessary to dissipate the heat generated by the internal electronic components.

The current handheld mobile device generally has a middle frame or a case as a base seat for supporting the respective units such as the electronic components and the touch screen. The middle frame or the case is generally an integrated structure body made by means of mechanical processing. The manufacturers in this field often additionally arrange assistant heat transfer members such as copper foil, graphite sheet, thin heat pipe and two-phase flow heat exchange unit in the mobile device to spread and dissipate the heat generated by the internal electronic components or conduct the heat to a remote end to dissipate the heat.

The integrated middle frame case 3 is made of one single material by means of mechanical processing such as milling or punching. The single material is selectively aluminum or aluminum alloy or copper alloy. In the case that a lightweight material is selectively used, the structural strength of the handheld device will be deteriorated. On the other hand, in the case that a material with better heat conductivity, such as pure copper, is selectively used, the heat conduction efficiency is enhanced, but the handheld device will be overweight. Moreover, the pure copper is soft and has poor structural strength. Therefore, the middle frame case 3 made of one single material cannot provide good heat conduction performance and sufficient structural strength at the same time.

Furthermore, as shown in FIG. 11, the conventional middle frame case 3 serves to support the respective electronic components 4 and the heat dissipation or heat conduction component 5. In case that the material of the middle frame case 3 has poor heat conduction performance, it is necessary to employ the heat dissipation or heat conduction component 5 to help in conducting the heat. The heat dissipation or heat conduction component 5 must be first attached to the middle frame case 3 and then laminated with the electronic component 4 to conduct the heat. Accordingly, the total thickness and weight of the middle frame case 3 are increased and the effect of thinning and lightweight can be hardly achieved.

It is therefore tried by the applicant to provide a heat dissipation structure of handheld device, which is selectively made of different materials in combination with each other, whereby the different materials can provide respective necessary material properties to achieve the effect of lightweight and thinning. Moreover, the heat dissipation structure of handheld device can enhance the heat conduction efficiency as well as the structural strength of the handheld device.

### SUMMARY OF THE INVENTION

It is therefore a primary object of the present invention to provide a heat dissipation structure of handheld device, which is made of multiple materials in combination with each other. The multiple materials can provide respective necessary material properties to achieve better heat conduction efficiency and better structural strength of the handheld device.

To achieve the above and other objects, the heat dissipation structure of handheld device of the present invention includes a hollow frame body and a two-phase flow heat exchange unit.

The hollow frame body has a hollow receiving space at the center. An inner periphery of the hollow frame body has a connection section. The two-phase flow heat exchange unit has at least one two-phase flow conduction section. An outer periphery of the two-phase flow conduction section has a lip section. The two-phase flow heat exchange unit is disposed in the hollow receiving space. The lip section is securely connected with the connection section.

The hollow frame body and the two-phase flow heat exchange unit are respectively made of different materials and then assembled with each other. Therefore, the two-phase flow heat exchange unit can enhance the heat conduction performance of the handheld device. Moreover, the hollow frame body is selectively made of a material with better structural strength so that the structural strength of the handheld device is enhanced.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a perspective exploded view of a first embodiment of the heat dissipation structure of handheld device of the present invention;

FIG. 2 is a sectional assembled view of the first embodiment of the heat dissipation structure of handheld device of the present invention;

FIG. 3 is a sectional view of a second embodiment of the heat dissipation structure of handheld device of the present invention;

FIG. 4 is a sectional view of a third embodiment of the heat dissipation structure of handheld device of the present invention;

FIG. 5 is a perspective exploded view of a fourth embodiment of the heat dissipation structure of handheld device of the present invention;

FIG. 6 is a perspective assembled view of the fourth embodiment of the heat dissipation structure of handheld device of the present invention;

FIG. 7 is a perspective exploded view of a fifth embodiment of the heat dissipation structure of handheld device of the present invention;

FIG. 8 is a sectional assembled view of the fifth embodiment of the heat dissipation structure of handheld device of the present invention;

FIG. 9 is a perspective exploded view of a sixth embodiment of the heat dissipation structure of handheld device of the present invention;

FIG. 10 is a sectional assembled view of the sixth embodiment of the heat dissipation structure of handheld device of the present invention; and

FIG. 11 is a sectional view of a conventional heat dissipation structure of handheld device.

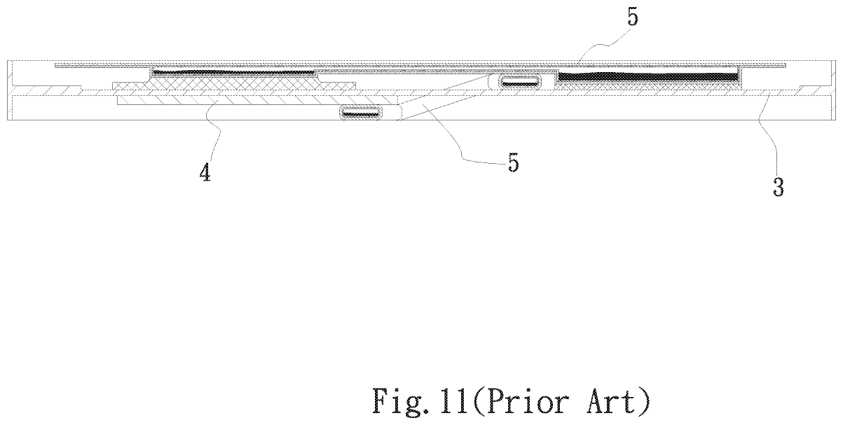

### DETAILED DESCRIPTION OF THE PREFERRED EMBODIMENTS

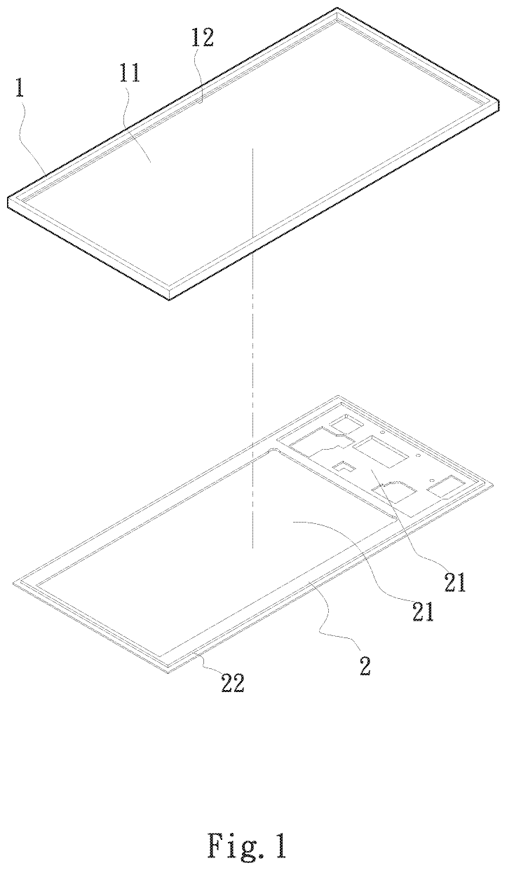

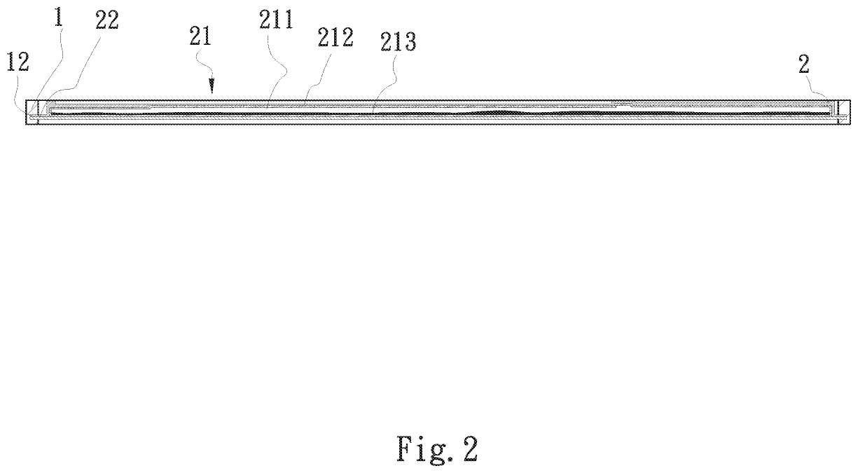

Please refer to FIGS. 1 and 2. FIG. 1 is a perspective exploded view of a first embodiment of the heat dissipation structure of handheld device of the present invention. FIG. 2 is a sectional assembled view of the first embodiment of the heat dissipation structure of handheld device of the present invention. As shown in the drawings, the heat dissipation structure of handheld device of the present invention includes a hollow frame body 1 and a two-phase flow heat exchange unit 2.

The hollow frame body 1 has at least one hollow receiving space 11 in any place. In this embodiment, the hollow frame body 1 has the hollow receiving space 11 at the center. The hollow receiving space 11 has two open ends. An inner periphery of the hollow frame body 1 has a connection section 12 in contact and connection with the two-phase flow heat exchange unit 2.

The two-phase flow heat exchange unit 2 has at least one two-phase flow conduction section 21. An outer periphery of the two-phase flow conduction section 21 has a lip section 22. The two-phase flow heat exchange unit 2 is disposed in the hollow receiving space 11 and the lip section 22 is securely connected with the connection section 12. The connection section 22 is connected with the lip section 22 by means of welding, adhesion, engagement, press fit, insertion or buckling. In this embodiment, the connection section 12 is a channel and the lip section 22 is inserted in the channel to connect with the hollow frame body 1. The two-phase flow heat exchange unit 2 is a vapor chamber or a flat-plate heat pipe. In this embodiment, the two-phase flow heat exchange unit 2 is, but not limited to, a vapor chamber for illustration.

The two-phase flow conduction section 21 has an airtight chamber 211 inside. An inner wall of the airtight chamber 211 has a capillary structure 212. A working liquid 213 is filled in the airtight chamber 211.

The hollow frame body 1 and the two-phase flow heat exchange unit 2 are made of a material selected from a group consisting of copper, aluminum, stainless steel, ceramic, commercial pure titanium, titanium alloy, copper alloy and aluminum alloy. In addition, the hollow frame body 1 and the two-phase flow heat exchange unit 2 are selectively made of different materials in combination with each other, whereby the different materials can provide respective necessary material properties to enhance the heat conduction efficiency and structural strength.

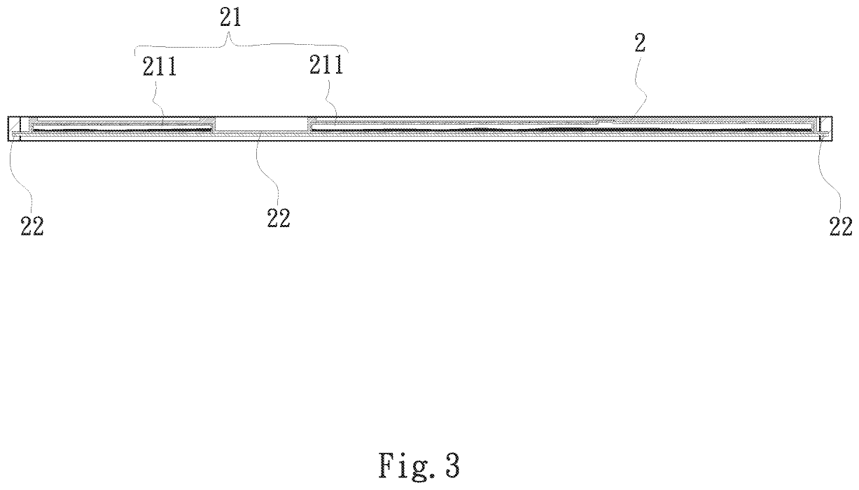

Please refer to FIG. 3, which is a sectional view of a second embodiment of the heat dissipation structure of handheld device of the present invention. The second embodiment is partially identical to the first embodiment in structure and thus will not be redundantly described hereinafter. The second embodiment is different from the first embodiment in that the two-phase flow conduction section 21 of the second embodiment is composed of multiple independent airtight chambers 211. The independent airtight chambers 211 are distributed over the respective parts of the two-phase flow heat exchange unit 2. The lip section 22 surrounds the independent airtight chambers 211. That is, in this embodiment, the two-phase flow conduction section 21 of the two-phase flow heat exchange unit 2 has multiple independent airtight chambers 211, which are respectively independently distributed over different parts of the two-phase flow heat exchange unit 2 so as to provide high heat transfer effect for the corresponding electronic components disposed in positions of the multiple independent airtight chambers 211.

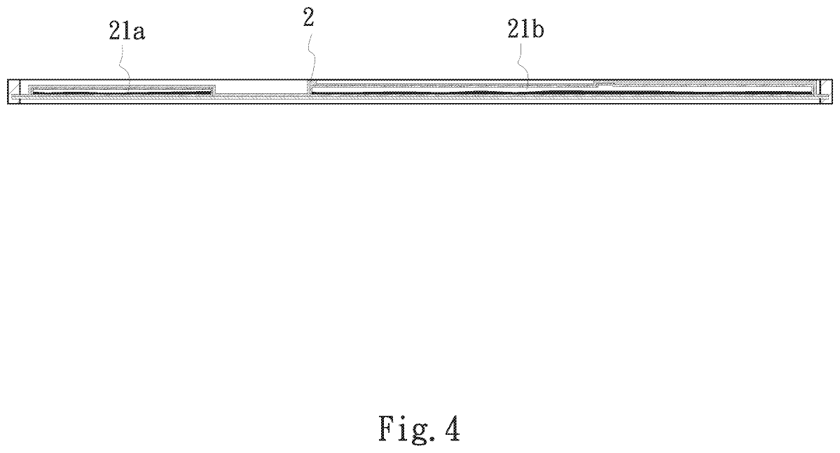

Please refer to FIG. 4, which is a sectional view of a third embodiment of the heat dissipation structure of handheld device of the present invention. The third embodiment is partially identical to the first embodiment in structure and thus will not be redundantly described hereinafter. The third embodiment is different from the first embodiment in that the two-phase flow conduction section 21 of the third embodiment has a first airtight chamber 21a and a second airtight chamber 21b. The first and second airtight chambers 21a, 21b are respectively disposed at the upper and lower ends of the two-phase flow heat exchange unit 2. In addition, the first airtight chamber 21a is higher than the second airtight chamber 21b. In this embodiment, the first and second airtight chambers 21a, 21b are disposed at different heights, whereby different heights or thicknesses of electronic components can be correspondingly assembled and disposed and the first and second airtight chambers 21a, 21b can provide corresponding heat conduction sections in a limited space.

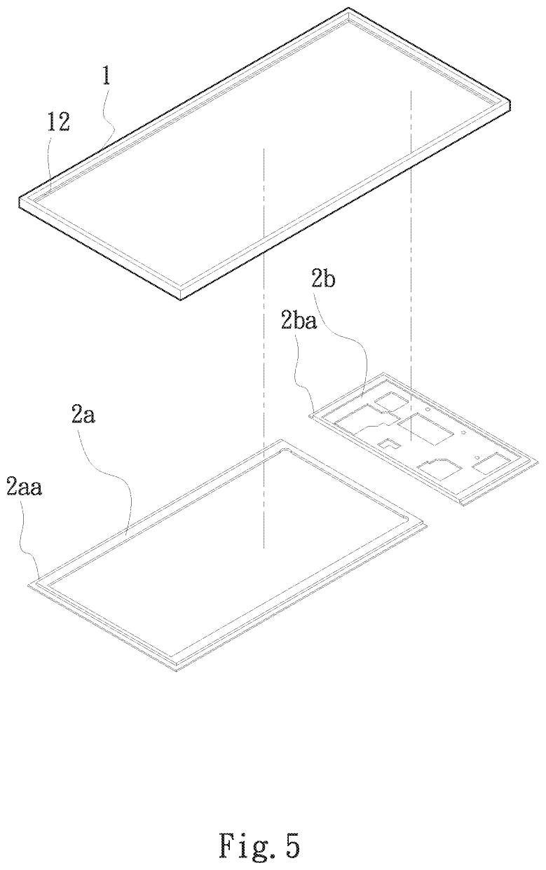

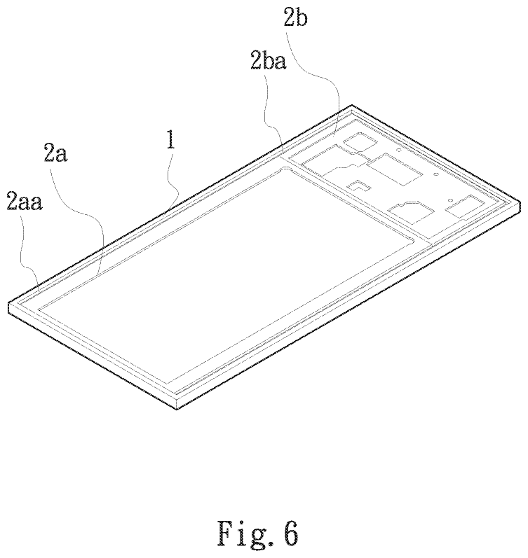

Please refer to FIGS. 5 and 6. FIG. 5 is a perspective exploded view of a fourth embodiment of the heat dissipation structure of handheld device of the present invention. FIG. 6 is a perspective assembled view of the fourth embodiment of the heat dissipation structure of handheld device of the present invention. The fourth embodiment is partially identical to the first embodiment in structure and thus will not be redundantly described hereinafter. The fourth embodiment is different from the first embodiment in that the two-phase flow heat exchange unit 2 of the fourth embodiment has a first vapor chamber 2a and a second vapor chamber 2b. The lip sections 2aa, 2ba of the first and second vapor chambers 2a, 2b are connected with each other. In addition, the lip sections 2aa, 2ba of the outer periphery of the first and second vapor chambers 2a, 2b are connected with the connection section 12 of the hollow frame body 1. That is, the corresponding lip sections 2aa, 2ba of the first and second vapor chambers 2a, 2b are first integrally connected by means of welding, adhesion, engagement, press fit or insertion. Then the lip sections 2aa, 2ba of the outer peripheries of the first and second vapor chambers 2a, 2b are connected and assembled with the hollow frame body 1 by means of welding, adhesion, engagement, press fit or insertion.

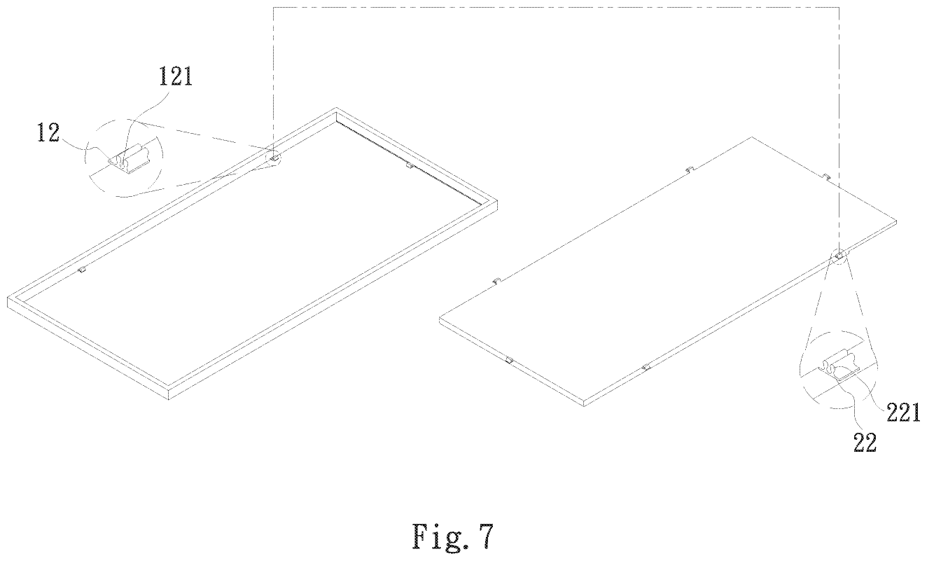

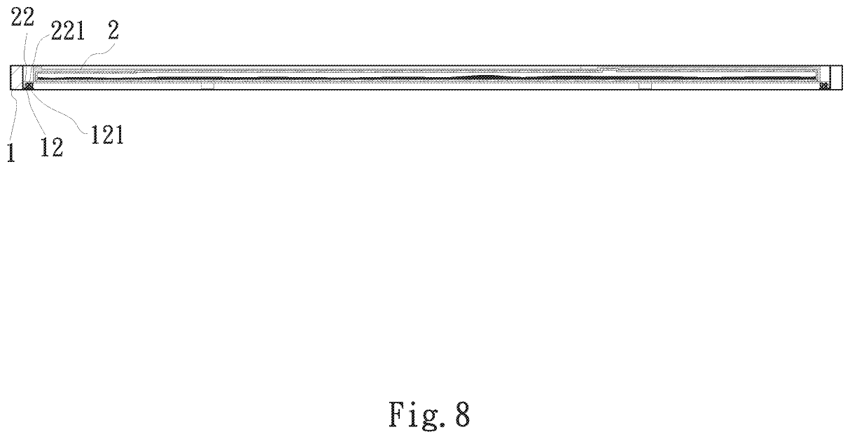

Please refer to FIGS. 7 and 8. FIG. 7 is a perspective exploded view of a fifth embodiment of the heat dissipation structure of handheld device of the present invention. FIG. 8 is a sectional assembled view of the fifth embodiment of the heat dissipation structure of handheld device of the present invention. The fifth embodiment is partially identical to the first embodiment in structure and thus will not be redundantly described hereinafter. The fifth embodiment is different from the first embodiment in that the lip section 22 of the fifth embodiment has an engagement end 221 and the connection section 12 has an engagement socket 121. The engagement end 221 is elastic and engaged in the engagement socket 121 and securely connected therewith, whereby the hollow frame body 1 is integrally connected with the two-phase flow heat exchange unit 2.

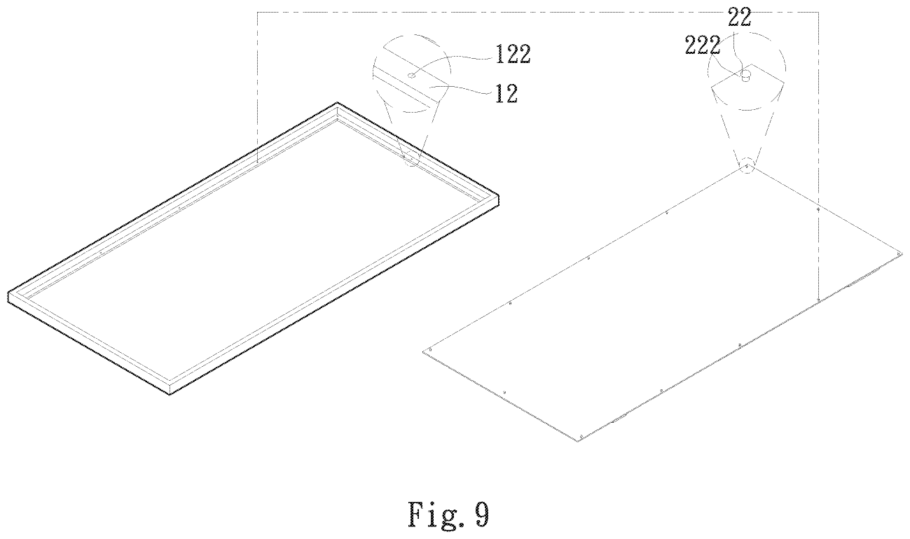

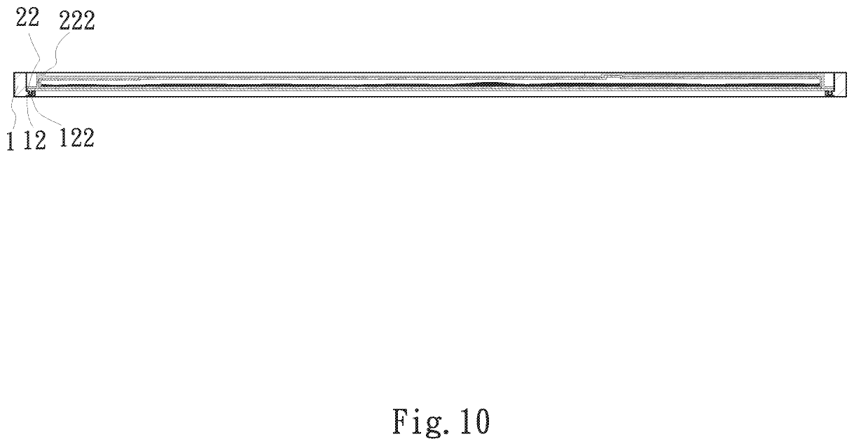

Please refer to FIGS. 9 and 10. FIG. 9 is a perspective exploded view of a sixth embodiment of the heat dissipation structure of handheld device of the present invention. FIG. 10 is a sectional assembled view of the sixth embodiment of the heat dissipation structure of handheld device of the present invention. The sixth embodiment is partially identical to the first embodiment in structure and thus will not be redundantly described hereinafter. The sixth embodiment is different from the first embodiment in that the lip section 22 of the sixth embodiment has a stud end 221 and the connection section 12 has an eyelet 122. The stud end 222 is buckled in the eyelet 122 and securely connected therewith, whereby the hollow frame body 1 is integrally connected with the two-phase flow heat exchange unit 2.

In the present invention, the hollow frame body and the two-phase flow heat exchange unit are first independently manufactured and then connected with each other. Accordingly, the hollow frame body 1 and the two-phase flow heat exchange unit 2 can be selectively made of different materials. The different materials have different material properties to respectively enhance the structural strength and promote the heat conduction performance. With respect to the section necessitating better structural strength, stainless steel or titanium or titanium alloy is selectively used to provide better support strength. In the present invention, the hollow frame body 1 is connected with the two-phase flow heat exchange unit 2 as an assembly. The two-phase flow heat exchange unit 2 with two-phase flow heat exchange effect can be directly used to support the electronic components and perform heat conduction work. In the precondition that the number of the heat transfer members is not increased and the thickness is not increased, the heat dissipation and heat transfer member can be omitted so that the total weight and thickness are greatly reduced to achieve the object of lightweight and thinning. Therefore, the shortcoming of the conventional heat dissipation structure of handheld device that only one single material can be selectively used to provide one single material property is improved.

The present invention has been described with the above embodiments thereof and it is understood that many changes and modifications in such as the form or layout pattern or practicing step of the above embodiments can be carried out without departing from the scope and the spirit of the invention that is intended to be limited only by the appended claims.

What is claimed is:

1. A heat dissipation structure of handheld device, comprising:
a hollow frame body having a hollow receiving space, an inner periphery of the hollow frame body having a connection section;
at least one two-phase flow heat exchange unit having at least one two-phase flow conduction section, the two-phase flow heat exchange unit being disposed in the hollow receiving space and securely connected with the hollow frame body.

2. The heat dissipation structure of handheld device as claimed in claim 1, wherein the inner periphery of the hollow frame body has a connection section, an outer periphery of the two-phase flow conduction section having a lip section, the lip section being connected with the connection section by means of welding, adhesion, engagement, press fit, insertion or buckling.

3. The heat dissipation structure of handheld device as claimed in claim 1, wherein the hollow frame body and the two-phase flow heat exchange unit are made of different materials.

4. The heat dissipation structure of handheld device as claimed in claim 1, wherein the connection section is a channel and the lip section is inserted in the channel to connect with the hollow frame body.

5. The heat dissipation structure of handheld device as claimed in claim 1, wherein the two-phase flow conduction section has an airtight chamber inside, an inner wall of the airtight chamber having a capillary structure, a working liquid being filled in the airtight chamber.

6. The heat dissipation structure of handheld device as claimed in claim 1, wherein the two-phase flow conduction section is composed of multiple independent airtight chambers, the independent airtight chambers being distributed over the respective parts of the two-phase flow heat exchange unit, the lip section surrounding the independent airtight chambers.

7. The heat dissipation structure of handheld device as claimed in claim 1, wherein the hollow frame body and the two-phase flow heat exchange unit are made of a material selected from a group consisting of copper, aluminum, stainless steel, ceramic, commercial pure titanium, titanium alloy, copper alloy and aluminum alloy.

8. The heat dissipation structure of handheld device as claimed in claim 1, wherein the two-phase flow conduction section has a first airtight chamber and a second airtight chamber, the first and second airtight chambers being respectively disposed at upper and lower ends of the two-phase flow heat exchange unit, the first airtight chamber being higher than the second airtight chamber.

9. The heat dissipation structure of handheld device as claimed in claim 1, wherein the two-phase flow heat exchange unit has a first vapor chamber and a second vapor chamber, the lip sections of the first and second vapor chambers being connected with each other, the lip sections of the outer peripheries of the first and second vapor chambers being connected with the connection section of the hollow frame body.

10. The heat dissipation structure of handheld device as claimed in claim 1, wherein the two-phase flow heat exchange unit is a vapor chamber or a flat-plate heat pipe.
